(19) United States
(12) Patent Application Publication
(10) Pub. No.: US 2002/0094659 A1
(43) Pub. Date: Jul. 18, 2002

(54) Method for forming isolation layer of semiconductor device

(76) Inventors: Chang Gyu Kim, Kyoungki-do (KR); Wan Shick Kim, Kyoungki-do (KR)

Correspondence Address: WILDMAN, HARROLD, ALLEN & DIXON, 225 WEST WACKER DRIVE, CHICAGO, IL, 60606, US

(21) Appl. No.: 09/992,389

(22) Filed: Nov. 14, 2001

(30) Foreign Application Priority Data
Jan. 12, 2001 (KR) 2001-01847

(51) Int. Cl. H01L 21/76

(52) U.S. Cl. 438/424

(57) ABSTRACT

A method for forming an isolation layer of a semiconductor device is disclosed. The method has a wet etching separately performed two times or more after the chemical mechanical polishing process. In the method, a silicon substrate having an active region and a field region is provided, and a trench is formed in the silicon substrate within the field region. An insulating layer to be used as the isolation layer is then formed on the silicon substrate including the trench. Thus the trench is filled with the insulating layer. Next, a capping layer is formed on a resultant entire structure including the insulating layer, and selectively removed by the chemical mechanical polishing process to expose an upper portion of the insulating layer in the active region. A point in time when the upper portion is exposed is used as an end point of the selective removal. Then a first wet etching is performed to remove the exposed insulating layer in the active region, and a second wet etching is performed to remove the residual capping layer. Accordingly, the insulating layer remaining in the trench establishes the isolation layer.

### BACKGROUND OF THE INVENTION

1. Field of the Invention

The present invention relates generally to a method for forming a semiconductor device. More particularly, the present invention relates to a method for forming an isolation layer of the semiconductor device, preferably adaptable to fabrication of a shallow trench isolation layer employed for electrically isolating unit devices from each other.

2. Description of the Related Art

In general, the semiconductor memory device has a plurality of cells integrated into a limited area. Each cell, composed of the unit devices such as a transistor and a capacitor, requires an electrical isolation from the other cells for independent operation characteristics.

As ways to realize an electrical isolation between the cells, a local oxidation of silicon (LOCOS) technology and a shallow trench isolation (STI) technology are well known in the art. The LOCOS technology grows a field oxide layer as a medium of isolation in a recess place of a silicon substrate, while the STI technology fills insulating material as an isolation medium in a vertically etched place of the silicon substrate.

In the LOCOS technology, the oxide layer has small stress and excellent quality since the silicon substrate in itself is thermally oxidized with a simple process. However, the LOCOS technology has a serious limitation on reduction in size of the device due to a large area required for the electrical isolation, and also a problem of bird's beak.

The STI technology has an advantage over the LOCOS technology in regard to the isolation area size and the bird's beak problem. In the STI technology, a trench is formed in the silicon substrate by a dry etching such as a reactive ion etching (RIE) or a plasma etching, and then filled with insulating material. Therefore, an insulating layer formed in the trench can be free from the bird's beak problem, occupying a relatively smaller isolation area. Additionally, the STI technology permits an improvement in junction leakage current property.

In a conventional STI process, a pad oxide layer is thermally grown on a silicon substrate, and a nitride layer is then deposited thereon by a chemical vapor deposition (CVD). Next, a photoresist layer is coated on the nitride layer and patterned into a photoresist pattern for trench formation. With the photoresist pattern being used as a mask, the nitride layer and the pad oxide layer are selectively removed by a dry etching. Then, the exposed silicon substrate is etched to a certain depth so as to form a trench in an isolation region.

Next, the photoresist pattern is removed in a stripping process and the silicon substrate is cleaned. The silicon substrate exposed through the nitride layer is then thermally oxidized to grow an oxide layer on an inner wall of the trench. Thereafter, an insulating layer of trench-filling material is deposited over the entire silicon substrate by a chemical vapor deposition (CVD), so that the trench is completely filled with the insulating layer. The insulating layer in the trench may be then optionally annealed for densification.

Next, the insulating layer is planarized in a chemical mechanical polishing (CMP) process, so that a top surface of the insulating layer becomes parallel with that of the nitride layer. The nitride layer and the pad oxide layer are then removed in a wet etching or a dry etching. The STI process is therefore completed to electrically isolate the cells of the device.

The CMP process is one of planarization technologies basically performed in the STI process so as to obtain a photolithographic margin and minimize interconnection wiring length, coping with high integration of the device. Though boro-phospho silicate glass (BPSG) reflow, aluminum reflow, and spin on glass (SOG) or photoresist etch back techniques are widely known as alternatives to the CMP process as the planarization technology in the art, the CMP process is advantageously applied to current devices for reasons of more global blanket removal at a lower temperature.

During the CMP process, a surface of a wafer, for example, the insulating layer, is polished by chemical reaction and mechanical abrasion of polishing slurry and a polishing pad. Unfortunately, particles contained in the polishing slurry may be agglutinated and thereby produce scratches on the polished surface. In addition, waste or transformation of the polishing pad or a backing film used together with the polishing pad may undesirably affect the CMP process.

In the polishing slurry, the particles may vary in distribution, depending upon a storing method thereof, a mixing process with deionized water or chemicals such as surface-active agent, a pipe arrangement from a storing tank to a polishing apparatus, and a flow rate. Therefore, the particles are unstably dispersed in the slurry, so that a large particle may be formed by agglutination of the particles in the slurry.

Seriously, the agglutinated particle can produce the scratches on the surface of the wafer during the CMP process. Also, the scratches may tend to spread in a following cleaning process. Besides, grains of diamond used for a pad conditioner may be detached from the pad conditioner and then also produce the scratches.

Moreover, the polishing rate varies according to the number of wafers subjected to the polishing process or time required for the polishing process, which may cause a process margin to be lowered. Therefore, a sample polishing operation should be needed to certify process stability. The sample polishing may additionally require a dummy wafer processing step and a monitoring step for checking results in the preceding process, thereby lowering the rate of operation.

Furthermore, when the polishing amount does not reach the objective one, the polishing operation should be repeated to remove non-polished parts. On the other hand, when the polishing amount exceeds the objective one, an active device region may be damaged or the shallow trench isolation region may have a poor profile.

### SUMMARY OF THE INVENTION

It is therefore an object of the present invention to provide an improved method for forming an isolation layer of a semiconductor device, permitting removal of damages caused by a chemical mechanical polishing process, allowing a reduction in time required for the chemical mechanical polishing process, and thereby enhancing reliability of the device.

This and other objects in accordance with the present invention are attained by a method, which has a wet etching separately performed two times or more after the chemical mechanical polishing process.

The method according to the present invention comprises providing a silicon substrate in which an active region and a field region are defined, and forming a trench in the silicon substrate within the field region. In the method of the present invention, an insulating layer to be used as the isolation layer is then formed on the silicon substrate including the trench. Thus the trench is filled with the insulating layer. Next, a capping layer is formed on a resultant entire structure including the insulating layer, and selectively removed by the chemical mechanical polishing process to expose an upper portion of the insulating layer within the active region. A point in time when the upper portion is exposed is used as an end point of the selective removal. Then, a first wet etching is performed to remove the exposed insulating layer within the active region, and a second wet etching is performed to remove the residual capping layer. Accordingly, the insulating layer remaining in the trench establishes the isolation layer.

In the method, the insulating layer may have a first portion filled in the trench within the field region and a second portion formed on the silicon substrate within the active region. The first portion may be physically separated from the second portion. Preferably, a high density plasma undoped silicate glass (HDP-USG) layer may be used as the insulating layer. Furthermore, the insulating layer may be deposited to a great height on a relatively broad part of the active region and also to a small height on a relatively narrow part of the active region. Moreover, the selective removal of the capping layer may include removing the capping layer on the insulating layer with a great height. In addition, the capping layer may be deposited with nitride by a plasma enhanced chemical vapor deposition (PECVD) or a low pressure chemical vapor deposition (LPCVD).

According to an alternate aspect of the present invention, another method for forming an isolation layer of a semiconductor device is provided. The method comprises providing a silicon substrate having an active region and a field region, sequentially forming a pad oxide layer and an etch stop layer on the silicon substrate, and forming a trench in the silicon substrate to define the field region by selectively removing the etch stop layer, the pad oxide layer, and an upper portion of the silicon substrate. In the method, an insulating layer to be used for the isolation layer is then formed on the etch stop layer and the trench region, so that the trench is filled with the insulating layer. Next, a sacrificial layer is formed on a resultant entire structure including the insulating layer.

The method further comprises selectively removing the sacrificial layer by a chemical mechanical polishing to expose an upper portion of the insulating layer in the active region, wherein a point in time when the upper portion is exposed is used as an end point of the selective removal. Thereafter, a first wet etching is performed to remove the insulating layer in the active region, and a second wet etching is performed to remove the whole sacrificial layer and the etch stop layer. Next, the pad oxide layer is removed, so that the isolation layer is established by the insulating layer remaining in the trench.

The etch stop layer may include a silicon nitride layer or a polysilicon layer, while the insulating layer may include a high density plasma undoped silicate glass (HDP-USG) layer. The insulating layer may be deposited to a great height on a relatively broad part of the active region and also to a small height on a relatively narrow part of the active region. Preferably, the sacrificial layer on the insulating layer with a great height may be removed in the selective removal, and further, the sacrificial layer on the insulating layer with a small height may be removed. Otherwise, the insulating layer under the sacrificial layer not removed by the chemical mechanical polishing may be removed by lift-off in the second wet etching.

The sacrificial layer may be deposited with nitride by a plasma enhanced chemical vapor deposition (PECVD) or a low pressure chemical vapor deposition (LPCVD). Moreover, the first wet etching may employ an etchant including diluted hydrogen fluoride (DHF) having a high selectivity to nitride, and the second wet etching may employ an etchant including phosphoric acid having a high selectivity to oxide. In addition, after the second wet etching, a third wet etching may be performed to adjust a height of the insulating layer remaining in the trench by employing an etchant having a high selectivity to nitride.

### BRIEF DESCRIPTION OF THE DRAWINGS

FIGS. 1 through 7 are cross-sectional views showing a sequence of processes for forming an isolation layer of a semiconductor device according to embodiments of the present invention. Particularly, while FIGS. 4A and 5A illustrate one embodiment of the present invention, FIGS. 4B and 5B illustrate another embodiment.

### DETAILED DESCRIPTION OF THE INVENTION

The present invention will now be described more fully hereinafter with reference to accompanying drawings, in which preferred embodiments of the invention are shown. This invention, however, be embodied in many different forms and should not be construed as limited to the embodiments set forth herein.

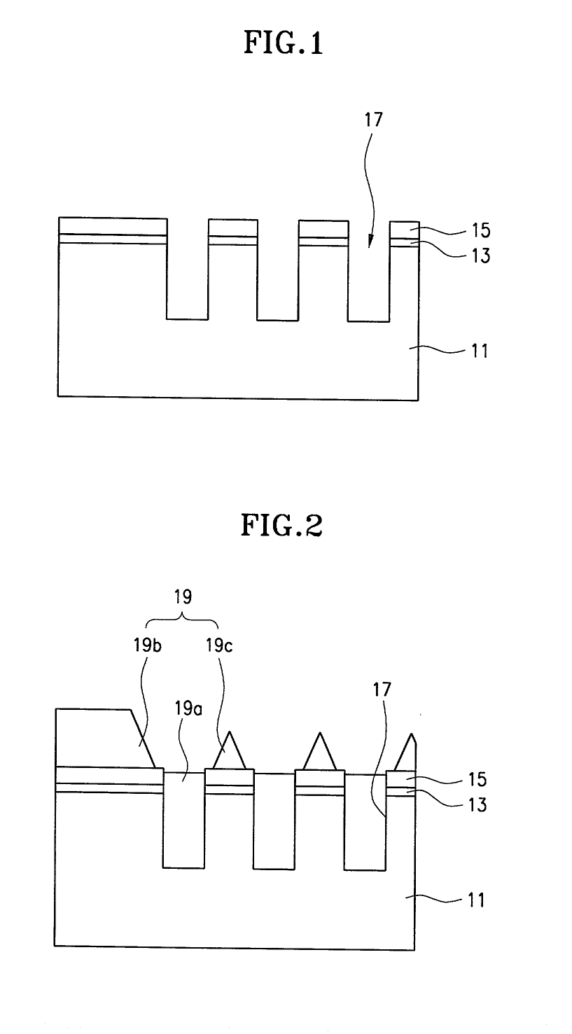

As shown in FIG. 1, after a silicon substrate 11 is provided, a pad oxide layer 13 and a silicon nitride layer 15 are sequentially formed on the silicon substrate 11. The silicon substrate 11 has an active region where a cell is formed and a field region where a trench 17 is to be formed for isolation between the adjacent cells. The pad oxide layer 13 is preferably formed with a thickness of several tens to hundreds angstrom by a thermal oxidation. The silicon nitride layer 15 is preferably formed with a thickness of hundreds angstrom by a chemical vapor deposition (CVD). Instead of the silicon nitride layer 15, a polysilicon layer may be alternatively used. The silicon nitride layer 15 or the polysilicon layer will act later as an etch stop layer.

Then, a proper resist pattern (not shown) is formed on the silicon nitride layer 15 through a photolithographic process. For example, a photoresist layer or a hard oxide layer may be employed for the resist pattern. With the resist pattern being used as a mask, the silicon nitride layer 15 and the pad oxide layer 13 are selectively removed and an upper portion of the silicon substrate 11 is also selectively removed. Thus a trench 17 is formed in the silicon substrate 11, while defining the field region.

Next, the resist pattern is removed and the silicon substrate 11 is cleaned. The silicon substrate 11 exposed through the silicon nitride layer 15 is then thermally oxidized, so that an oxide layer (not shown) is formed on an inner wall of the trench 17.

Thereafter, as shown in FIG. 2, an insulating layer 19 is deposited over the entire silicon substrate 11 by a high density plasma chemical vapor deposition (HDPCVD). Thereby, the trench 17 is completely filled with a first portion 19a of the insulating layer, and further, the silicon nitride layer 15 in the active region is almost covered with a second portion 19b and 19c of the insulating layer. The insulating layer 19a in the trench 17 may be then annealed for densification. Preferably, a top surface of the insulating layer 19a in the trench 17 is lower than that of the silicon nitride layer 15 and higher than that of the pad oxide layer 13. Therefore, the insulating layer 19a in the trench 17 is physically separated from the insulating layer 19b and 19c in the active region.

As the preferred insulating layer 19, a high density plasma undoped silicate glass (HDP-USG) layer may be used. The HDP-USG layer 19 has an excellent gap-filling property since a depositing operation thereof usually accompanies an etching operation. That is, with the advance of the depositing operation, a deposition rate is slowing down. Accordingly, as well depicted in FIG. 2, a part 19b of the HDP-USG layer is deposited to a great height on a relatively broad part of the active region, and the other part 19c of the HDP-USG layer is deposited to a small height on a relatively narrow part of the active region.

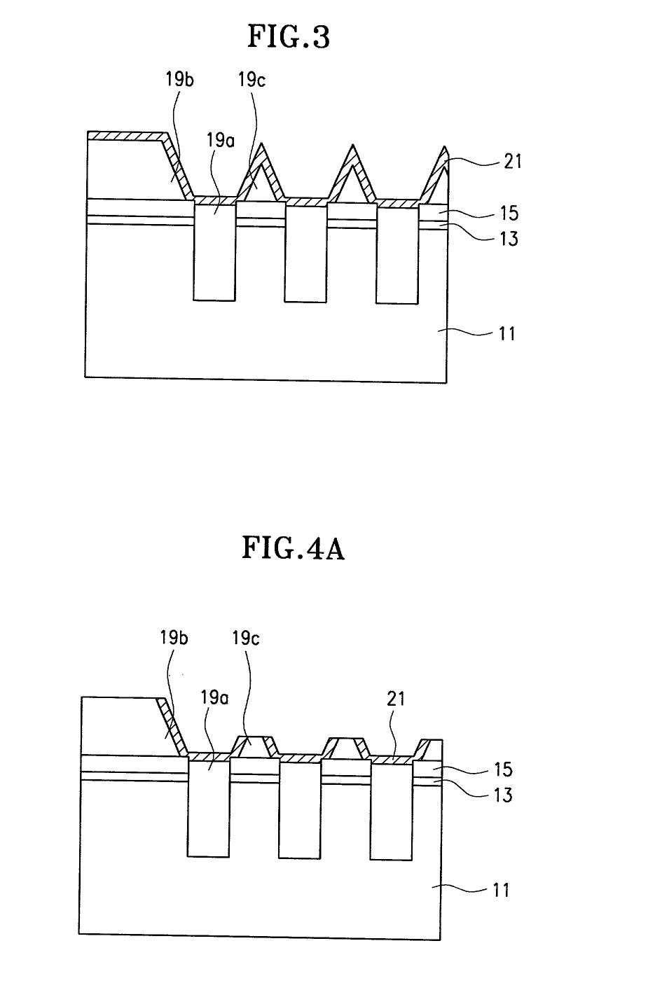

After the deposition of the insulating layer 19, as shown in FIG. 3, a sacrificial layer 21 is deposited on a resultant entire structure including the insulating layer 19. The sacrificial layer 21 is used as a capping layer for a planarization process to be performed later. Preferably, the sacrificial layer is formed with nitride by a plasma enhanced chemical vapor deposition (PECVD) or a low pressure chemical vapor deposition (LPCVD).

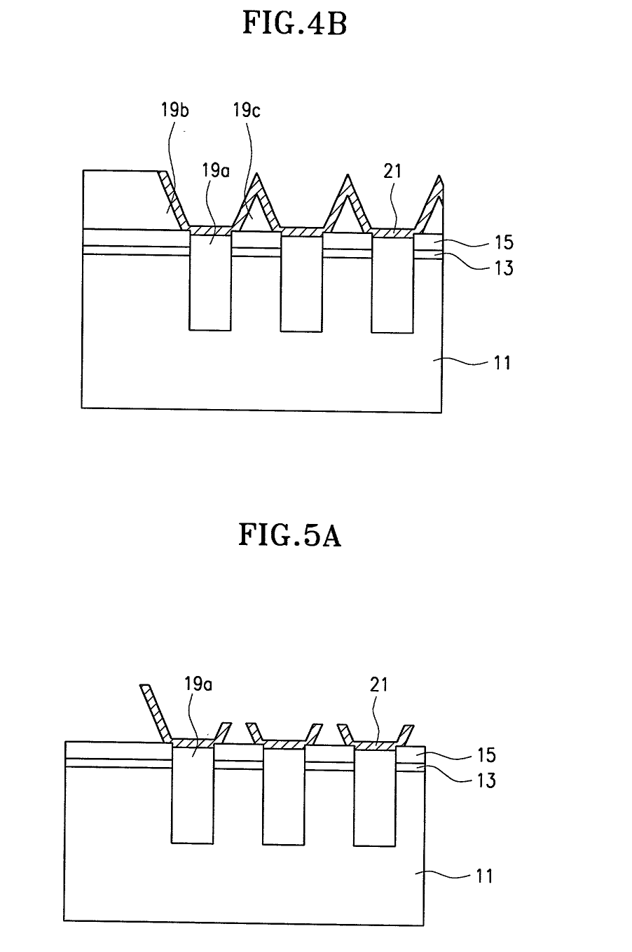

Next, as shown in FIGS. 4A and 4B, the sacrificial layer 21 is selectively removed by a chemical mechanical polishing (CMP) process so as to expose an upper portion of the insulating layer 19 in the active region. During the CMP process, a point in time when the upper portion of the insulating layer 19 is exposed is used as an end point of the selective removal.

The CMP process may use a soft polishing pad or a hard polishing pad. When the soft polishing pad is used, as shown in FIG. 4A, the sacrificial layer 21 is removed from the upper portions of the first part 19b of the insulating layer with a great height and of the second part 19c of the insulating layer with a small height. When the hard polishing pad is used alternatively, as shown in FIG. 4B, the sacrificial layer 21 is removed from the upper portion of the first part 19b only. In the latter case, the sacrificial layer 21 on the second part 19c of the insulating layer will be removed later.

After the CMP process, the first and the second wet etching steps are performed in sequence. In particular, a scratch or any other similar surface defects produced on the insulating layer 19 or the silicon nitride layer 15 in the CMP process will be removed during the first and the second wet etching steps.

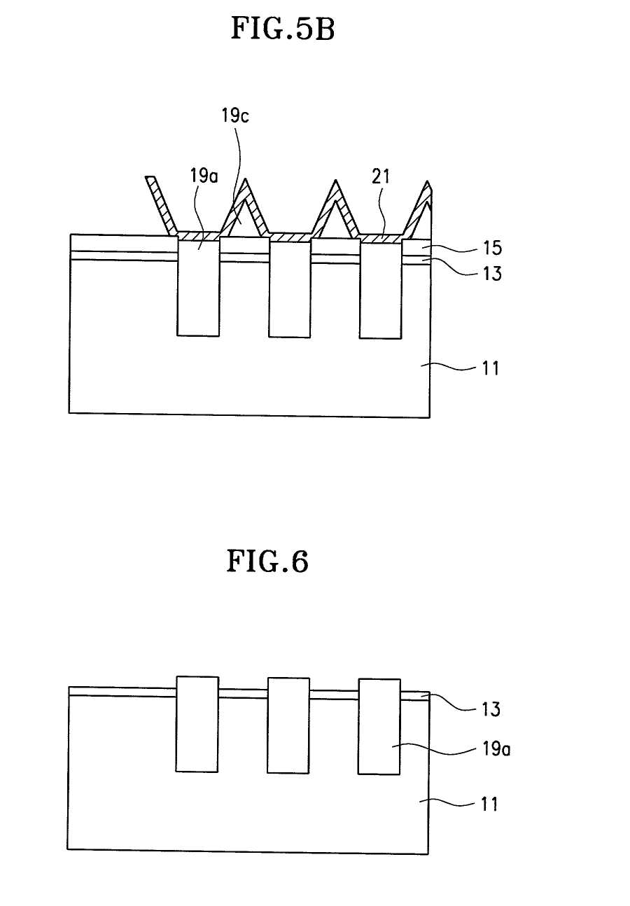

The first wet etching is performed to selectively remove the insulating layer 19 in the active region. As shown in FIGS. 5A and 5B, the insulating layer exposed through the residual sacrificial layer 21 is removed. The first wet etching uses an etchant having a high selectivity to nitride and thus allowing removal of oxide. Diluted hydrogen fluoride (DHF) is preferably used as the etchant of the first wet etching. In particular, during the first wet etching, the insulating layer 19a in the trench is not damaged because of the sacrificial layer 21.

Thereafter, the second wet etching is performed to wholly remove the residual sacrificial layer 21 and the silicon nitride layer 15. FIG. 6 shows a resultant structure after the second wet etching. The second wet etching uses an etchant, such as phosphoric acid, having a high selectivity to oxide and thus allowing removal of nitride. Furthermore, the second part, 19c shown in FIG. 5B, of the insulating layer in the active region, have been not removed by the former CMP process, is removed by lift-off in the second wet etching.

Moreover, as described above, undesired damage such as a scratch or any other similar surface defects produced in the CMP process is fully removed during the wet etching.

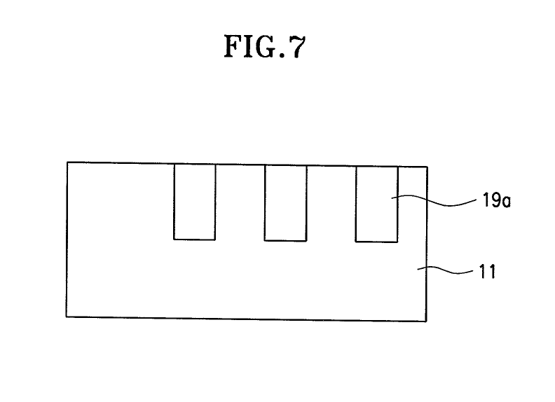

Then, the pad oxide layer 13 is removed by a reactive ion etching (RIE), and the insulating layer 19a remaining in the trench is partially etched to adjust a height thereof by using an etchant having a high selectivity to nitride. Accordingly, as shown in FIG. 7, a desired isolation layer is established by the insulating layer 19a in the trench.

As described above, the CMP process according to the present invention is limited to the selective removal of the sacrificial layer, causing an improved process margin and reduced polishing particles, and thus enhancing productivity.

Additionally, the wet etching process according to the present invention is used two times or more to remove non-polished layers after the CMP process, while removing undesired damage due to the CMP process, and thereby allowing improvement in process uniformity, reliability of the device, and yield of the device.

The present invention can be advantageously applied to a planarization process of interlayer dielectric as well as the shallow trench isolation (STI) process.

What is claimed is:

1. A method for forming an isolation layer of a semiconductor device, comprising:
providing a silicon substrate in which an active region and a field region are defined;
forming a trench in the silicon substrate within the field region;
forming an insulating layer to be used as the isolation layer on the silicon substrate including the trench, thereby filling the trench with the insulating layer;
forming a capping layer on a resultant entire structure including the insulating layer;
selectively removing the capping layer by a chemical mechanical polishing to expose an upper portion of the insulating layer within the active region, wherein a point in time when the upper portion is exposed is used as an end point of the selective removal;
performing a first wet etching to remove the exposed insulating layer within the active region; and
performing a second wet etching to remove the residual capping layer, so that the isolation layer is established by the insulating layer remaining in the trench.

2. The method of claim 1, wherein the insulating layer has a first portion filled in the trench within the field region and a second portion formed on the silicon substrate within the active region, and wherein the first portion is physically separated from the second portion.

3. The method of claim 1, wherein the insulating layer includes a high density plasma undoped silicate glass (HDP-USG) layer.

4. The method of claim 1, wherein the insulating layer is deposited to a great height on a relatively broad part of the active region and also to a small height on a relatively narrow part of the active region.

5. The method of claim 4, wherein the selectively removing of the capping layer includes removing the capping layer on the insulating layer with a great height.

6. The method of claim 1, wherein the capping layer is deposited with nitride by a plasma enhanced chemical vapor deposition (PECVD) or a low pressure chemical vapor deposition (LPCVD).

7. A method for forming an isolation layer of a semiconductor device, comprising:
providing a silicon substrate having an active region and a field region;
sequentially forming a pad oxide layer and an etch stop layer on the silicon substrate;
forming a trench in the silicon substrate to define the field region by selectively removing the etch stop layer, the pad oxide layer, and an upper portion of the silicon substrate;
forming an insulating layer to be used for the isolation layer on the etch stop layer and the trench region, thereby filling the trench with the insulating layer;
forming a sacrificial layer on a resultant entire structure including the insulating layer;
selectively removing the sacrificial layer by a chemical mechanical polishing to expose an upper portion of the insulating layer in the active region, wherein a point in time when the upper portion is exposed is used as an end point of the selective removal;
performing a first wet etching to remove the insulating layer in the active region;
performing a second wet etching to remove the whole sacrificial layer and the etch stop layer; and
removing the pad oxide layer, so that the isolation layer is established by the insulating layer remaining in the trench.

8. The method of claim 7, wherein the etch stop layer includes a silicon nitride layer or a polysilicon layer.

9. The method of claim 7, wherein the insulating layer includes a high density plasma undoped silicate glass (HDP-USG) layer.

10. The method of claim 7, wherein the insulating layer is deposited to a great height on a relatively broad part of the active region and also to a small height on a relatively narrow part of the active region.

11. The method of claim 10, wherein the selectively removing of the sacrificial layer includes removing the sacrificial layer on the insulating layer with a great height.

12. The method of claim 11, wherein the selectively removing of the sacrificial layer further includes removing the sacrificial layer on the insulating layer with a small height.

13. The method of claim 11, wherein the insulating layer under the sacrificial layer not removed by the chemical mechanical polishing is removed by lift-off in the second wet etching.

14. The method of claim 7, wherein the sacrificial layer is deposited with nitride by a plasma enhanced chemical vapor deposition (PECVD) or a low pressure chemical vapor deposition (LPCVD).

15. The method of claim 7, wherein the first wet etching employs an etchant including diluted hydrogen fluoride (DHF) having a high selectivity to nitride.

16. The method of claim 7, wherein the second wet etching employs an etchant including phosphoric acid having a high selectivity to oxide.

17. The method of claim 7, wherein after the second wet etching, a third wet etching is further performed to adjust a height of the insulating layer remaining in the trench by employing an etchant having a high selectivity to nitride.
